(19) United States
(12) Patent Application Publication
(10) Pub. No.: US 2025/0351611 A1
(43) Pub. Date: Nov. 13, 2025

(54) IMAGE SENSOR PACKAGING AND METHODS FOR FORMING THE SAME

(71) Applicant: Taiwan Semiconductor Manufacturing Company, Ltd., Hsinchu (TW)

(72) Inventors: Hao-Lin Yang, Kaohsiung City (TW); Tzu-Jui Wang, Kaohsiung County (TW); Wei-Cheng Hsu, Kaohsiung City (TW); Cheng-Jong Wang, Hsin-Chu (TW); Dun-Nian Yuang, Taipei City (TW); Kuan-Chieh Huang, Hsinchu City (TW)

(21) Appl. No.: 19/271,496

(22) Filed: Jul. 16, 2025

Related U.S. Application Data
(63) Continuation of application No. 18/155,491, filed on Jan. 17, 2023.
(60) Provisional application No. 63/408,531, filed on Sep. 21, 2022.

(51) Int. Cl. H10F 39/00; H10F 39/18

(52) U.S. Cl. CPC H10F 39/811; H10F 39/014; H10F 39/182; H10F 39/8037; H10F 39/809

(57) ABSTRACT

A device structure according to the present disclosure may include a first die having a first substrate and a first interconnect structure, a second die having a second substrate and a second interconnect structure, and a third die having a third interconnect structure and a third substrate. The first interconnect structure is bonded to the second substrate via a first plurality of bonding layers. The second interconnect structure is bonded to the third interconnect structure via a second plurality of bonding layers. The third substrate includes a plurality of photodiodes and a first transistor. The second die includes a second transistor having a source connected to a drain of the first transistor, a third transistor having a gate connected to drain of the first transistor and the source of the second transistor, and a fourth transistor having a drain connected to the source of the third transistor.

### PRIORITY DATA

This application is a continuation application of U.S. patent application Ser. No. 18/155,491, filed Jan. 17, 2023, which claims priority to U.S. Provisional Patent Application Ser. No. 63/408,531, filed Sep. 21, 2022, each of which is herein incorporated by reference in its entirety.

### BACKGROUND

Complementary metal-oxide semiconductor (CMOS) image sensors (CIS) are gaining popularity over traditional charged-coupled devices (CCDs). A CMOS image sensor typically includes an array of picture elements (pixels), which utilizes light-sensitive CMOS circuitry to convert photons into electrons. The light-sensitive CMOS circuitry typically may include a photodiode formed in a semiconductor substrate. As the photodiode is exposed to light, an electrical charge is induced in the photodiode. Each pixel may generate electrons proportional to the amount of incident light that falls on the pixel. The electrons are converted into a voltage signal in the pixel and further transformed into a digital signal which will be processed by an application specific integrated circuit (ASIC). Although existing image sensor packaging have been generally adequate for their intended purposes, they are not satisfactory in all respects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a schematic circuit diagram of an example image sensor element.

FIG. 2 is a schematic circuit diagram of an image sensor element, according to various aspects of the present disclosure.

FIG. 3 is a schematic circuit diagram of an alternative image sensor element, according to various aspects of the present disclosure.

FIG. 4 is a schematic cross-sectional view of an embodiment of an image sensor structure constructed in accordance with various aspects of the present disclosure.

FIG. 5 illustrates a flowchart of a method for forming an image sensor element, according to one or more aspects of the present disclosure.

FIG. 6 is a schematic cross-sectional view of a third die that includes photodiodes, according to various aspects of the present disclosure.

FIG. 7 is a schematic cross-sectional view of a second die that includes photodiode sensing circuitry, according to various aspects of the present disclosure.

FIG. 8 is a schematic cross-sectional view of the second die in FIG. 7 bonded to the third die in FIG. 6, according to various aspects of the present disclosure.

FIG. 9 is a schematic cross-sectional view of the bonded die stack in FIG. 8 where the second die is thinned, according to various aspects of the present disclosure.

FIG. 10 is a schematic cross-sectional view of the bonded die stack in FIG. 9 where bonding features are formed over the second die, according to various aspects of the present disclosure.

FIG. 11 is a schematic cross-sectional view of a first die bonded to the die stack in FIG. 10, according to various aspects of the present disclosure.

FIG. 12 is a schematic cross-sectional view of the die stack in FIG. 11 wherein the third die is thinned, according to various aspects of the present disclosure.

FIG. 13 is a schematic cross-sectional view of another embodiment of an image sensor structure constructed in accordance with various aspects of the present disclosure.

FIG. 14 is a schematic cross-sectional view of a third die that includes photodiodes, according to various aspects of the present disclosure.

FIG. 15 is a schematic cross-sectional view of a second die that includes photodiode sensing circuitry, according to various aspects of the present disclosure.

FIG. 16 is a schematic cross-sectional view of the second die in FIG. 15 bonded to the third die in FIG. 14, according to various aspects of the present disclosure.

FIG. 17 is a schematic cross-sectional view of the bonded die stack in FIG. 16 where the second die is thinned, according to various aspects of the present disclosure.

FIG. 18 is a schematic cross-sectional view of the bonded die stack in FIG. 17 where bonding features are formed over the second die, according to various aspects of the present disclosure.

FIG. 19 is a schematic cross-sectional view of a first die bonded to the die stack in FIG. 17, according to various aspects of the present disclosure.

FIG. 20 is a schematic cross-sectional view of the die stack in FIG. 19 wherein the third die is thinned, according to various aspects of the present disclosure.

FIG. 21 illustrates a schematic top view of two adjacent image sensor cluster, according to various aspects of the present disclosure.

FIG. 22 illustrates a schematic top view of an image sensor cluster and electrical routing around the same, according to various aspects of the present disclosure.

FIG. 23 illustrates a schematic cross-sectional view of an image cluster and electrical routing around the same, according to various aspects of the present disclosure.

FIG. 24 illustrates a schematic cross-sectional view of a first type bonding layer, according to various aspects of the present disclosure.

FIG. 25 illustrates a schematic cross-sectional view of a second type bonding layer, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Complementary metal-oxide-semiconductor (CMOS) image sensors (CIS) have gained popularity in recent years. In some existing technologies, a CIS image sensor may include a pixel chip stacked over a logic chip. The pixel chip includes the photodiodes and pixel transistors and the logic chip includes application specific integrated circuit (ASIC). In some examples, the pixel transistors may include transfer gates (TX), a source follower (SF), a reset transistor (RST), and a row selector (SEL). In these existing technologies, the multiplicity of transistors in the pixel chip may take up space for photodiodes and make it difficult to reduce the pixel size.

The present disclosure provides a three-chip construction of an image sensor. An image sensor according to the present disclosure includes a first chip that includes logic transistors, a second chip that includes pixel transistors, and a third chip that includes photodiodes and transfer gates. The first chip include a first substrate and a first interconnect structure disposed over the first substrate. The second chip includes a second substrate and a second interconnect structure disposed over the second substrate. The third chip includes a third interconnect structure and a third substrate disposed over the third interconnect structure. The first chip and the second chip are bonded together such that the first interconnect structure is bonded to the second substrate by way of bonding layers and the second interconnect structure is also bonded to the third interconnect structure by way of bonding layers. By moving pixel transistors (such as source followers (SF), reset transistors (RST), and row selectors (SEL)) to the second chip, more space in the third chip may be made available for photodiodes and the pixel size may be reduced. Additionally, the use of the bonding layers prevents the necessity to form high-aspect-ratio through-substrate-vias after bonding of the second chip and the third chip.

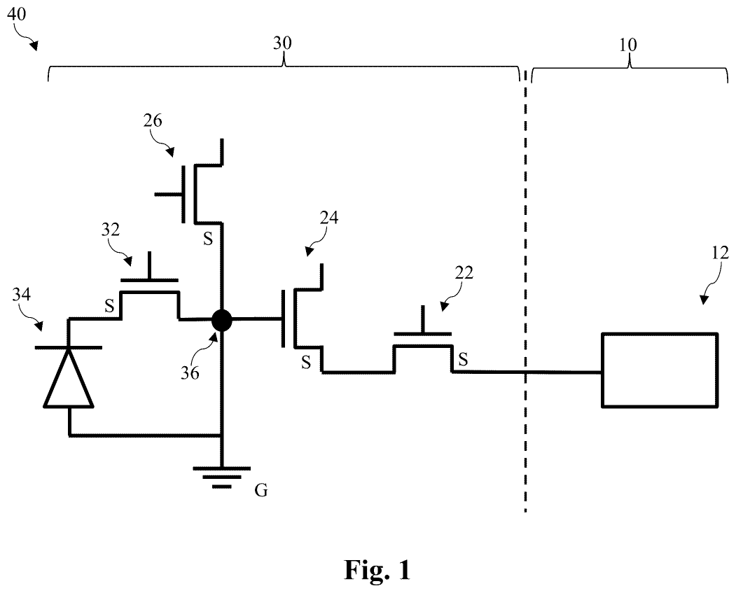

FIG. 1 illustrates a schematic circuit diagram of an image sensor element 40 that has a two-chip construction. In the depicted example, the image sensor element 40 is a complementary metal oxide semiconductor (CMOS) image sensor (CIS). As illustrated in FIG. 1, the image sensor element 40 includes an ASIC circuit 12, a row selector transistor 22, a source follower transistor 24, a reset transistor 26, and a transfer gate transistor 32, and a photodiode 34. In FIG. 1, the photodiode 34 is connected between a ground G and the source of the transfer gate transistor 32. The drain of the transfer gate transistor 32, the source of the reset transistor 26 and the gate of the source follower transistor 24 are all connected together at a floating diffusion (FD) node 36. The source of the source follower transistor 24 is coupled to the drain of the row selector transistor 22 and the source of the row selector transistor 22 is coupled to the ASIC circuit 12. In some existing technologies, the ASIC circuit 12 is fabricated on a first chip 10 while the row selector transistor 22, the source follower transistor 24, the reset transistor 26, the transfer gate transistor 32, and the photodiode 34 are fabricated on a third chip 30. In the example shown in FIG. 1, the first chip 10 may be referred to as a logic chip 10 or an ASIC chip 10 while the third chip 30 may be referred to as a pixel chip 30. The third chip 30 is bonded to the first chip 10 to form the image sensor element 40 shown in FIG. 1. In the two-chip construction shown in FIG. 1, the third chip 30 not only contains the photodiode 34, but also the row selector transistor 22, the source follower transistor 24, the reset transistor 26, and the transfer gate transistor 32. The presence of these transistors may take up space in the third chip 30 and limits the photo sensing area of the photodiode 34. Additionally, because the photodiode 34 in the third chip 30 comes with 4 transistors, the ability to shrink the dimensions of a pixel is hindered.

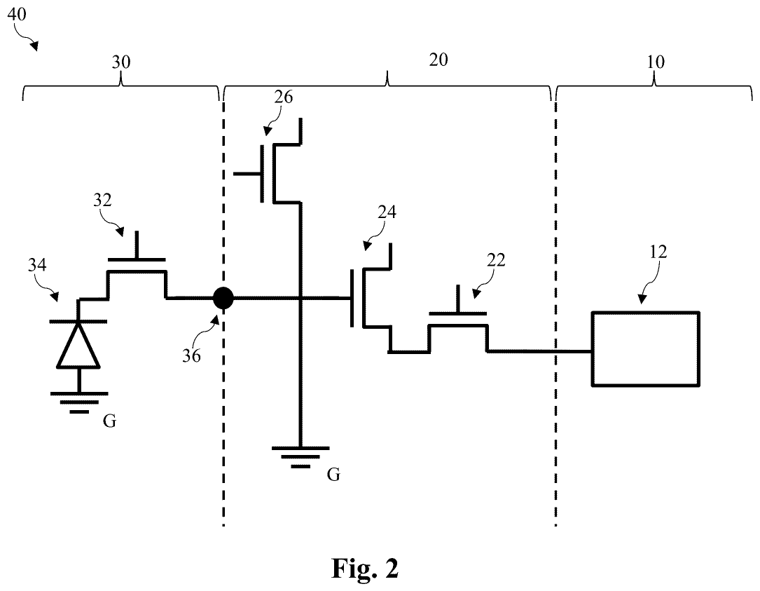

FIG. 2 illustrates a schematic circuit diagram of an image sensor element 40 that has a three-chip construction according to various aspects of the present disclosure. Like the image sensor element 40 shown in FIG. 1, the image sensor element 40 shown in FIG. 2 also includes an ASIC circuit 12, a row selector transistor 22, a source follower transistor 24, a reset transistor 26, and a transfer gate transistor 32, and a photodiode 34 that are electrically connected in the same manner. The photodiode 34 is connected between a ground G and the source of the transfer gate transistor 32. The drain of the transfer gate transistor 32, the source of the reset transistor 26 and the gate of the source follower transistor 24 are all connected together at a floating diffusion (FD) node 36. The source of the source follower transistor 24 is coupled to the drain of the row selector transistor 22 and the source of the row selector transistor 22 is coupled to the ASIC circuit 12. As indicated in FIG. 2, the ASIC circuit 12 is fabricated on a first chip 10; the row selector transistor 22, the source follower transistor 24, the reset transistor 26 are fabricated on a second chip 20; and the transfer gate transistor 32 and the photodiode 34 are fabricated on a third chip 30. In the depicted embodiment, the first chip 10 may be referred to as a logic chip 10 or an ASIC chip 10, the second chip 20 may be referred to as a pixel device chip 20, and the third chip 30 may be referred to as a pixel chip 30. The first chip 10, the second chip 20, and the third chip 30 are bonded together to form the image sensor element 40 shown in FIG. 2. In the three-chip construction shown in FIG. 2, the third chip 30 only contains the photodiode 34 and the transfer gate transistor 32. Compared to the image sensor element 40 in FIG. 1, the row selector transistor 22, the source follower transistor 24, and the reset transistor 26 are removed from the third chip 30 and moved to the second chip 20. The reduction of the transistors present in the third chip 30 not only increases the space available for the photodiodes 34 but also helps to reduce pixel sizes. While it logically follows that the transfer gate transistors 32 should also be moved to the second chip 20 to create even more space for the photodiode 34, the state-of-the-art image sensor construction requires that that transfer gate transistor 32 be adjacent to, if not extending into, the photodiodes 34. For that reasons, the transfer gate transistors 32 remain disposed in the third chip 30 in FIG. 2 and other figures of the present disclosure. Should a new design emerge where the transfer gate transistor 32 can be moved farther away from the photodiode 34, the transfer gate transistor 32 may be moved to the second chip 20.

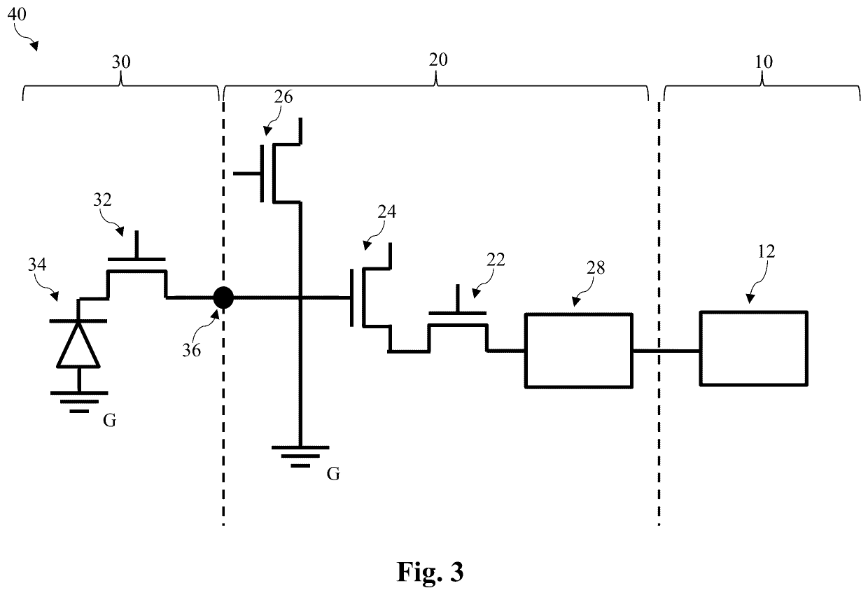

While the image sensor element 40 in FIG. 2 includes four transistors (i.e., a row selector transistor 22, a source follower transistor 24, a reset transistor 26, and a transfer gate transistor 32), it should be understood that the image sensor element 40 may include components in addition to the four transistors (4T). For example, the image sensor element 40 may include a pixel reset transistor to reset the photodiode or a capacitor (e.g., a metal-insulator-metal (MIM) capacitor or a deep trench capacitor) to store charges. FIG. 3 illustrates an image sensor element 40 that includes an additional pixel device 28 to represent a pixel reset transistor or a capacitor. In order to save the space in the third chip 30, the additional pixel device 28 is fabricated on the second chip 20. It should be understood that the electrical connections of the additional pixel device 28 in FIG. 3 are for illustration purpose only. The additional pixel device 28 is not required to be connected to the source of the row selector transistor 22 or the ASIC circuit 12.

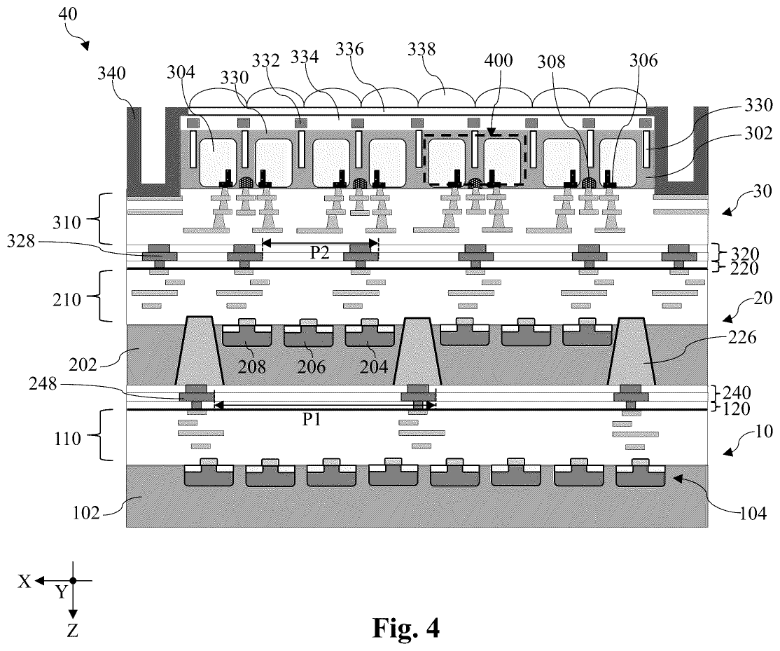

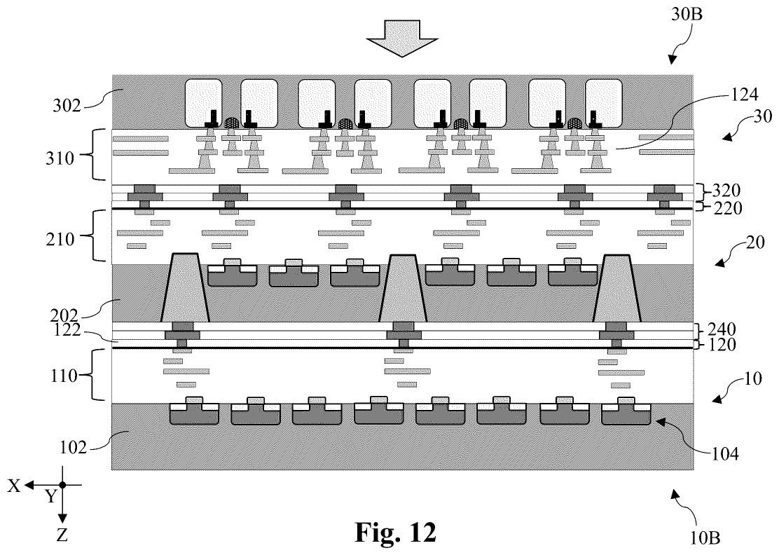

Depending on the design requirements, the image sensor element 40 shown in FIG. 2 may be implemented as three-chip constructions shown in FIGS. 4 and 12. Generally speaking, the image sensor element 40 shown in FIG. 4 includes small and compactly-packed photodiodes to boost pixel density while the image sensor element 40 shown in FIG. 12 includes large photodiodes to increase or maximize full well capacity. The former is benefited by the three-chip construction of the present disclosure because most of the pixel transistors (except for the transfer gate transistor 32) are moved to the second chip. The latter is also benefited by the three-chip construction of the present disclosure because the removal of the pixel transistors allow maximization of the photodiode dimensions.

Reference is now made to FIG. 4. The image sensor element 40 in FIG. 4 includes a first chip 10, a second chip 20, and a third chip 30. The first chip 10 includes a first substrate 102 and a first interconnect structure 110 disposed over the first substrate 102. A plurality of logic transistors 104 are fabricated in the first substrate 102. The first chip 10 includes a first bonding layer 120 disposed on the first interconnect structure 110. The second chip 20 includes a second substrate 202 and a second interconnect structure 210 disposed over the second substrate 202. Row selector transistors 204, source follower transistor 206, reset transistors 208 are fabricated in the second substrate 202. The second chip 20 includes a second bonding layer 220 disposed on the second interconnect structure 210 and a third bonding layer 240 disposed on the second substrate 202. Bonding contacts in the third bonding layer 240 are electrically coupled to through-substrate-vias (TSVs) 226 that extend completely through the second substrate 202. The third chip 30 includes a third interconnect structure 310 and a third substrate 302 disposed on the third interconnect structure 310. The third substrate 302 includes a plurality of photodiodes 304 that are divided by deep trench isolation (DTI) features 330. A transfer gate transistor 306 is disposed adjacent each of the photodiodes 304 to collect photo electrons. In the depicted embodiments, the gate of the transfer gate transistor 306 vertically extends into the respective photodiode 304 and such a gate may be referred to as a vertical transfer gate. A floating diffusion region 308 is formed in the third substrate 302 by implantation. The openings of the photodiodes 304 are defined by a metal grid 332. The third chip 30 further includes a color filter layer 336 and microlens 338. For electrical connections, the third chip 30 may include metal pads 340. Because the image sensor element 40 in FIG. 4 includes photodiodes 304 that are disposed over the third interconnect structures, the image sensor element 40 is a backside-illuminated (BSI) sensor. The third chip 30 includes a fourth bonding layer 320 disposed on the third interconnect structure 310.

For avoidance of doubts, the first chip 10 shown in FIG. 4 generally corresponds to the first chip 10 illustrated in FIG. 1, 2 or 3. The second chip 20 shown in FIG. 4 generally corresponds to the second chip 20 illustrated in FIG. 2 or 3. The third chip 30 shown in FIG. 4 generally corresponds to the third chip 30 shown in FIG. 2 or 3. For example, the first chip 10 in FIGS. 1-4 includes logic transistors (or ASIC transistors). The second chip 20 in FIGS. 2-4 includes row selector transistors, source follower transistors, and reset transistors. The third chip 30 in FIGS. 2-4 includes photodiodes and transfer gate transistors.

Reference is still made to FIG. 4. The second chip 20 is bonded to the first chip 10 by directly bonding the first bonding layer 120 to the third bonding layer 240. As such, the second substrate 202 is adjacent the first interconnect structure 110 and the second interconnect structure 210 is away from the first interconnect structure 110. The third chip 30 is bonded to the second chip 20 by directly bonding the second bonding layer 220 to the fourth bonding layer 320. As such, the third interconnect structure 310 is adjacent the second interconnect structure 210 and the third substrate 302 is away from the second interconnect structure 210.

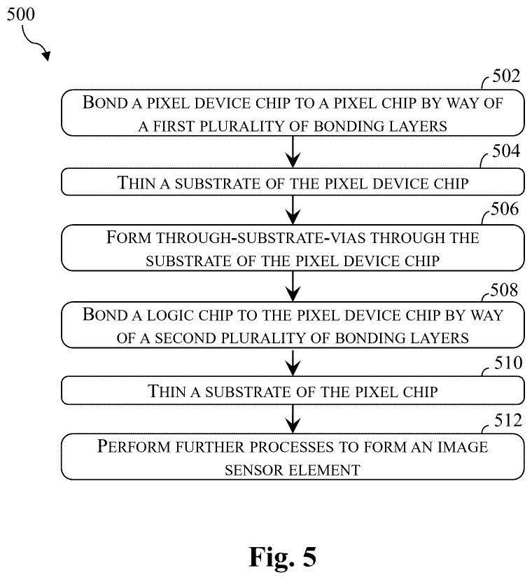

FIG. 5 illustrates a flowchart of a method 500 of forming an image sensor element 40 shown in FIG. 4 or FIG. 12. Method 500 is merely an example and is not intended to limit the present disclosure to what is explicitly illustrated in method 500. Additional steps may be provided before, during and after method 500, and some steps described can be replaced, eliminated, or moved around for additional embodiments of the methods. Not all steps are described herein in detail for reasons of simplicity. Method 500 is described below in conjunction with FIGS. 4, 6-25, which illustrate fragmentary cross-sectional views different stages of fabrication according to method 500. The X direction, the Y direction, and the Z direction in FIGS. 4 and 6-25 are perpendicular to one another and are used consistently. Additionally, throughout the present disclosure, like reference numerals are used to denote like features.

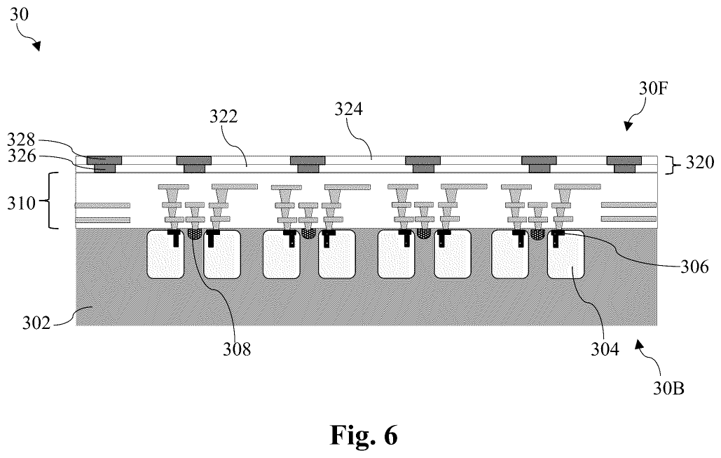

FIGS. 4 and 6-12 illustrate fabrication of the image sensor element 40 in FIG. 4 using method 500 in FIG. 5. Referring to FIGS. 5-8, method 500 includes a block 502 where a pixel device chip is bonded to a pixel chip by way of a first plurality of bonding layer. FIG. 6 illustrates a third chip 30, which is a pixel chip. The third chip 30 includes a third substrate 302 and a third interconnect structure 310. For ease of reference, the third chip 30 includes a front side 30F adjacent the third interconnect structure 310 and a back side 30B adjacent the third substrate 302. The third substrate 302 may be a bulk silicon (Si) substrate. Alternatively, the third substrate 302 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof.

The third substrate 302 includes a plurality of photodiodes 304. To form the photodiodes 304 in the third substrate 302, the third substrate 302 can include various doped regions. In one embodiment, the third substrate 302 may include n-type dopants, such as phosphorus (P), arsenic (As), or other n-type dopants. The third chip 30 further includes transfer gate transistors 306 adjacent a photodiode 304 or extending into a photodiode 304 to collect photoelectrons. The third substrate 302 further includes heavily doped regions between or among photodiodes to form floating diffusion (FD) nodes 308. In some embodiments, the floating diffusion nodes 308 are heavily doped with n-type dopants (n+). The third interconnect structure 310 includes a plurality of metal layers. Each of the plurality of metal layers includes contact vias and metal lines disposed in at least one etch stop layer and at least one intermetal dielectric (IMD) layer. The contact vias and metal lines may include copper and barrier layers formed of titanium, titanium nitride, tantalum, tantalum nitride, cobalt, cobalt nitride, nickel, or nickel nitride. The etch stop layers in the third interconnect structure 310 may include silicon nitride, silicon carbide, silicon oxynitride, or a combination thereof. The IMD layer may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

The third chip 30 includes a fourth bonding layer 320 deposited on the front side 30F of the third chip 30. That is, the fourth bonding layer 320 is deposited on the third interconnect structure 310 and provides bonding surfaces and allows inter-substrate communication. In some embodiments represented in FIG. 6 the fourth bonding layer 320 includes a plurality of bonding contacts 326 disposed in a first dielectric bonding layer 322 and a plurality bonding pads 328 disposed in a second dielectric bonding layer 324. The first dielectric bonding layer 322 and the second dielectric bonding layer 324 may include silicon oxide or silicon oxynitride. The plurality of bonding contacts 326 and a plurality of bonding pads 328 may include copper (Cu), tantalum (Ta), nickel (Ni), cobalt (Co), aluminum (Al), a combination thereof, or an alloy thereof. In one embodiment, the plurality of bonding contacts 326 and a plurality of bonding pads 328 include copper (Cu). As shown in FIG. 6, each of the plurality of bonding pads 328 is vertically aligned or vertically overlaps with one of the plurality of bonding contacts 326 along the Z direction. As will be described further below, each of the plurality of bonding pads 328 is vertically aligned with a floating diffusion (FD) node 308.

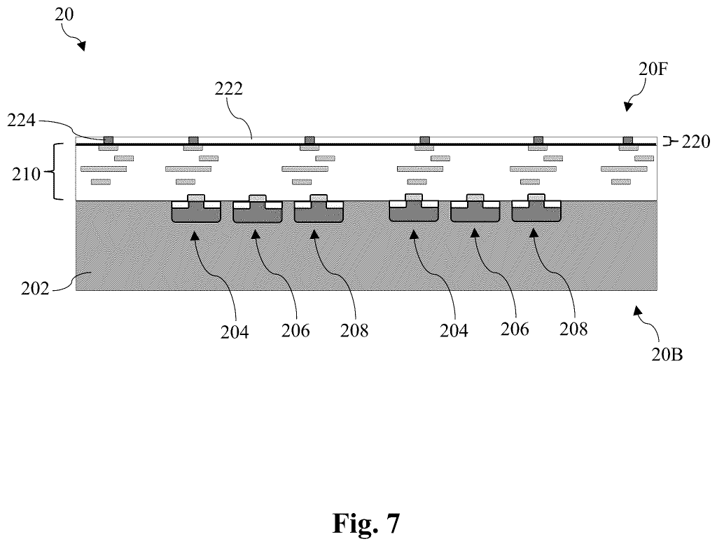

FIG. 7 illustrates a second chip 20, which is a pixel device chip. The second chip 20 includes a second substrate 202 and a second interconnect structure 210. For ease of reference, the second chip 20 includes a front side 20F adjacent the second interconnect structure 210 and a back side 20B adjacent the second substrate 202. The second substrate 202 may be a bulk silicon (Si) substrate. Alternatively, the second substrate 202 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof.

The second substrate 202 includes row selector transistors 204, source follower transistors 206, and reset transistors 208. The row selector transistors 204, source follower transistor 206, and reset transistors 208 correspond to row selector transistors 22, source follower transistors 24, and reset transistors 26, respectively. The row selector transistors 204, source follower transistor 206, and reset transistors 208 may be implemented using planar transistors or multi-gate transistors. Example multi-gate transistors may include fin-like field effect transistor (FinFETs) or gate-all-around (GAA) transistors. A planar transistor includes a gate structure that may induce a planar channel region along one surface of its active region, hence its name. A FinFET includes a fin-shaped active region arising from a substrate and a gate structure disposed over a top surface and sidewalls of the fin-shaped active region. A GAA transistor includes at least one channel member extending between two source/drain features and a gate structure that wraps completely around the at least one channel member. Because its gate structure wraps around the channel member, a GAA transistor may also be referred to as a surrounding gate transistor (SGT). Depending on the shapes and orientation, a channel member in a GAA transistor may be referred to as a nanosheet, a semiconductor wire, a nanowire, a nanostructure, a nano-post, a nano-beam, or a nano-bridge. In some instances, a GAA transistor may be referred to by the shape of the channel member. For example, a GAA transistor having one or more nanosheet channel member may also be referred to as a nanosheet transistor or a nanosheet FET.

The second interconnect structure 210 includes a plurality of metal layers. Each of the plurality of metal layers includes contact vias and metal lines disposed in at least one etch stop layer and at least one intermetal dielectric (IMD) layer. The contact vias and metal lines may include copper and barrier layers formed of titanium, titanium nitride, tantalum, tantalum nitride, cobalt, cobalt nitride, nickel, or nickel nitride. The etch stop layers in the third interconnect structure 310 may include silicon nitride, silicon carbide, silicon oxynitride, or a combination thereof. The IMD layer may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

The second chip 20 includes a second bonding layer 220 deposited on the front side 20F of the second chip 20. That is, the second bonding layer 220 is deposited on the second interconnect structure 210 and provides bonding surfaces and allows inter-substrate communication. In some embodiments represented in FIG. 7, the second bonding layer 220 includes a plurality of bonding contacts 224 disposed in a third dielectric bonding layer 222. The third dielectric bonding layer 222 may include silicon oxide or silicon oxynitride. The plurality of bonding contacts 224 may include copper (Cu), tantalum (Ta), nickel (Ni), cobalt (Co), aluminum (Al), a combination thereof, or an alloy thereof. In one embodiment, the plurality of bonding contacts 224 include copper (Cu). It is noted that the second bonding layer 220 shown in FIG. 7 only includes bonding contacts but does not include bonding pads similar to the bonding pads 328. In some alternative embodiments not explicitly shown in FIG. 7, the second bonding layer 220 may further include a plurality of bonding pads that are vertically aligned with the bonding contacts.

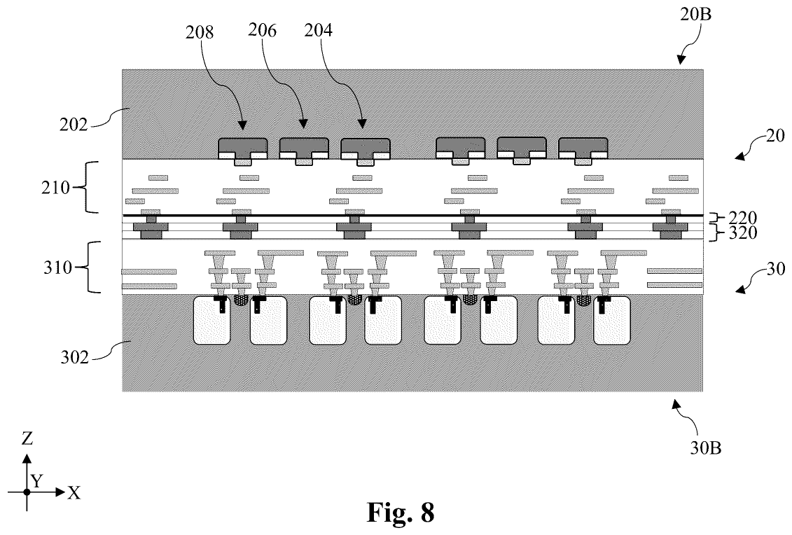

Referring to FIG. 8, operations at block 502 include flipping over the second chip 20 shown in FIG. 7 and bonding the same to the third chip 30 shown in FIG. 6. To bond the second chip 20 to the third chip 30, each of the bonding contacts 224 in the second bonding layer 220 is aligned to one of the bonding pads 328 in the fourth bonding layer 320. A direct bonding process is then performed to bond the second chip 20 to the third chip 30 such that, as described further below, dielectric surfaces are bonded to dielectric surfaces and metal surfaces are bonded to metal surfaces. To ensure a strong bonding between the second bonding layer 220 and the fourth bonding layer 320, surfaces of the second bonding layer 220 and the fourth bonding layer 320 are cleaned to remove organic and metallic contaminants. In an example process, a sulfuric acid hydrogen peroxide mixture (SPM), a mixture of ammonium hydroxide and hydrogen peroxide (SC1), or both may be used to remove organic contaminants on the second bonding layer 220 and the fourth bonding layer 320. A mixture of hydrochloric acid and hydrogen peroxide (SC2) may be used to remove metallic contaminants. Besides cleaning, the bonding contacts 224 and the bonding pads 328 may be treated by an argon plasma or a nitrogen plasma to activate the surfaces thereof. After the bonding contacts 224 and the bonding pads 328 are aligned, an anneal is performed to promote the van der Waals force bonding of the first dielectric bonding layer 322 and the third dielectric bonding layer 222 as well as the surface-activated bonding (SAB) of the bonding pads 328 and the bonding contacts 224. In the depicted example, the first plurality of bonding layers at block 502 include the second bonding layer 220 and the fourth bonding layer 320.

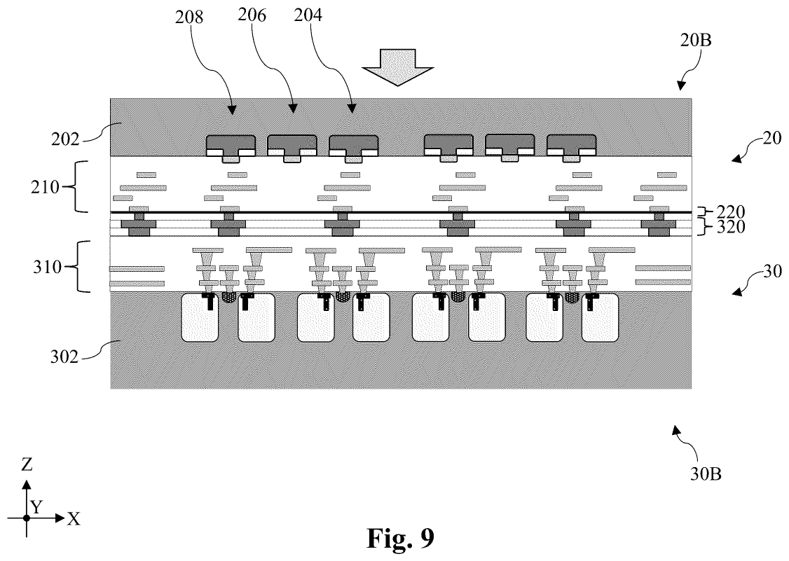

Referring to FIGS. 5 and 9, method 500 includes a block 504 where a substrate of the pixel device chip is thinned. The chip stack shown in FIG. 8 includes the second chip 20, which corresponds to a pixel device chip. At block 504, the second substrate 202 of the second chip is thinned. The chip stack shown in FIG. 9, which includes the third chip 30 and the second chip 20, may undergo multiple thinning and polishing steps to reduce the thickness of the second substrate 202. In an example process, diamond wheels may be used to perform coarse grinding, fine grinding, or super fine grinding and a chemical mechanical polishing (CMP) process may be performed to polishing the ground second substrate 202. The thinning of the second substate 202 helps reduce the aspect ratio of the through-substrate openings for the through-substrate-vias 226 (to be described below).

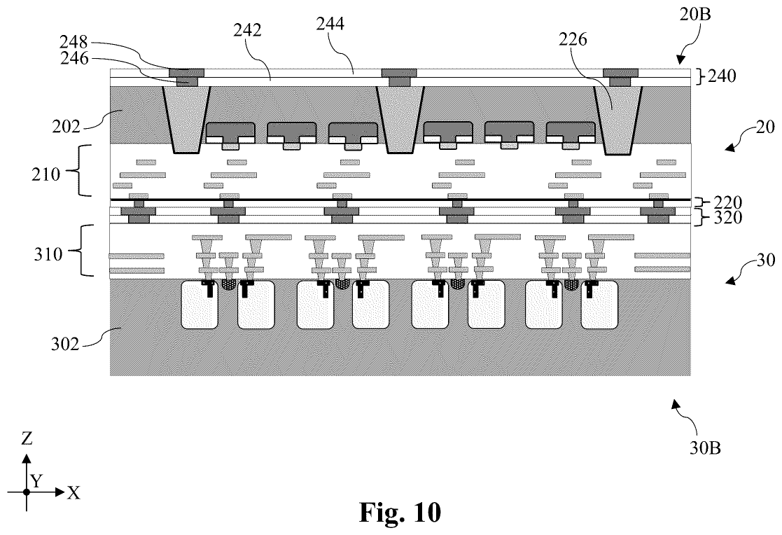

Referring to FIGS. 5 and 10, method 500 includes a block 506 where through-substrate-vias are formed through the substrate of the pixel device chip. As shown in FIG. 10, the second chip 20 corresponds to the pixel device chip and at block 506, through-substrate-vias (TSVs) 226 are formed through the second substrate 202 of the second chip 20. The TSVs 226 function to redirect electrical signals to the back side 20B of the second chip 20 to interface a third bonding layer 240. In an example process, via openings are formed through the second substrate 202 using dry etching, such as reactive-ion-etching (RIE). After the via openings are formed, a conductive material is then deposited in the via openings to form the TSVs 226. The conductive material may include copper (Cu). To prevent electromigration of coppers, the via openings may be lined with a barrier layer before deposition of the conductive material. In some instances, the barrier layer may include titanium nitride.

After the formation of the TSVs 226, a third bonding layer 240 is formed over the thinned second substrate 202. The third bonding layer 240 includes a plurality of bonding contacts 246 disposed in a fourth dielectric bonding layer 242 and a plurality bonding pads 248 disposed in a fifth dielectric bonding layer 244. The fourth dielectric bonding layer 242 and fifth dielectric bonding layer 244 may include silicon oxide or silicon oxynitride. The plurality of bonding contacts 246 and a plurality of bonding pads 248 may include copper (Cu), tantalum (Ta), nickel (Ni), cobalt (Co), aluminum (Al), a combination thereof, or an alloy thereof. In one embodiment, the plurality of bonding contacts 246 and a plurality of bonding pads 248 include copper (Cu). As shown in FIG. 10, each of the plurality of bonding pads 248 is vertically aligned or overlaps with one of the plurality of bonding contacts 246 along the Z direction. Furthermore, each of the plurality of bonding contacts 246 is vertically aligned with one of the TSVs 226.

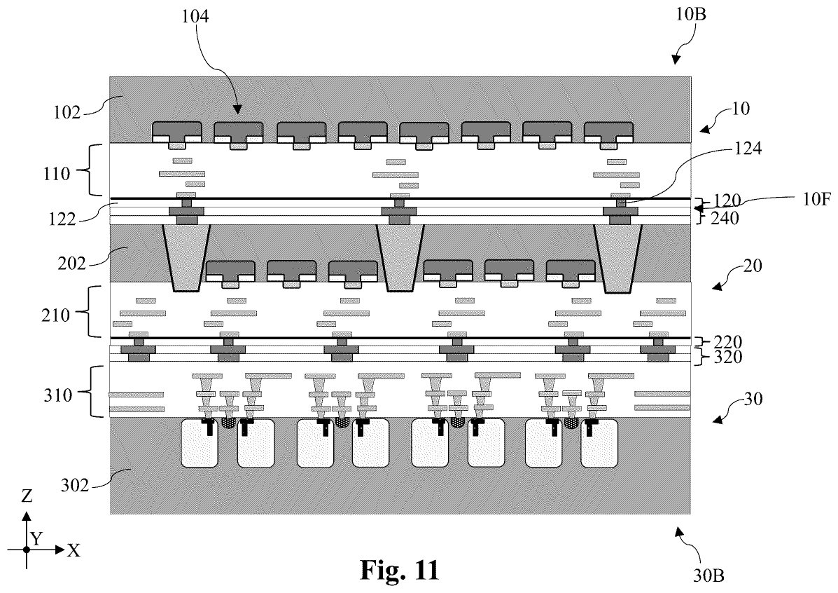

Referring to FIGS. 5 and 11, method 500 includes a block 508 where a logic chip is bonded to the pixel device chip by way of a second plurality of bonding layers. The first chip 10 corresponds to the logic chip and may be referred to as a logic chip 10. The first chip 10 includes a first interconnect structure 110 and a first substrate 102 disposed over the first interconnect structure 110. For ease of reference, the first chip 10 includes a front side 10F adjacent the first interconnect structure 110 and a back side 10B adjacent a surface of the first interconnect structure 110. The first substrate 102 may be a bulk silicon (Si) substrate. Alternatively, the first substrate 102 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof.

The first substrate 102 includes a plurality of logic transistors 104. The logic transistors 104 correspond to the ASIC circuit 12 shown in FIG. 2 or 3. The logic transistors 104 may be implemented using planar transistors or multi-gate transistors. Example multi-gate transistors may include fin-like field effect transistor (FinFETs) or gate-all-around (GAA) transistors. A planar transistor includes a gate structure that may induce a planar channel region along one surface of its active region, hence its name. A FinFET includes a fin-shaped active region arising from a substrate and a gate structure disposed over a top surface and sidewalls of the fin-shaped active region. A GAA transistor includes at least one channel member extending between two source/drain features and a gate structure that wraps completely around the at least one channel member. Because its gate structure wraps around the channel member, a GAA transistor may also be referred to as a surrounding gate transistor (SGT). Depending on the shapes and orientation, a channel member in a GAA transistor may be referred to as a nanosheet, a semiconductor wire, a nanowire, a nanostructure, a nano-post, a nano-beam, or a nano-bridge. In some instances, a GAA transistor may be referred to by the shape of the channel member. For example, a GAA transistor having one or more nanosheet channel member may also be referred to as a nanosheet transistor or a nanosheet FET.

The first interconnect structure 110 includes a plurality of metal layers. Each of the plurality of metal layers includes contact vias and metal lines disposed in at least one etch stop layer and at least one intermetal dielectric (IMD) layer. The contact vias and metal lines may include copper and barrier layers formed of titanium, titanium nitride, tantalum, tantalum nitride, cobalt, cobalt nitride, nickel, or nickel nitride. The etch stop layers in the first interconnect structure 110 may include silicon nitride, silicon carbide, silicon oxynitride, or a combination thereof. The IMD layer may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

The first chip 10 includes a first bonding layer 120 deposited on the front side 10F of the first chip 10. That is, the first bonding layer 120 is deposited on the second interconnect structure 210 and provides bonding surfaces and allows inter-substrate communication. In some embodiments represented in FIG. 11, the first bonding layer 120 includes a plurality of bonding contacts 124 disposed in a sixth dielectric bonding layer 122. The sixth dielectric bonding layer 122 may include silicon oxide or silicon oxynitride. The plurality of bonding contacts 124 may include copper (Cu), tantalum (Ta), nickel (Ni), cobalt (Co), aluminum (Al), a combination thereof, or an alloy thereof. In one embodiment, the plurality of bonding contacts 124 include copper (Cu). It is noted that the first bonding layer 120 shown in FIG. 11 only includes bonding contacts 124 but does not include bonding pads similar to the bonding pads 328. In some alternative embodiments not explicitly shown in FIG. 11, the first bonding layer 120 may further include a plurality of bonding pads that are vertically aligned with the bonding contacts.

Referring to FIG. 11, operations at block 502 include bonding the first chip 10 to the second chip 20 by way of the third bonding layer 240 and the first bonding layer 120. To bond first chip 10 to the second chip 20, each of the bonding contacts 124 in the first bonding layer 120 is aligned to one of the bonding pads 248 in the third bonding layer 240. A direct bonding process is then performed to bond the first chip 10 to the second chip 20 such that, as described below, dielectric surfaces are bonded to dielectric surfaces and metal surfaces are bonded to metal surfaces. To ensure a strong bonding between the first bonding layer 120 and the third bonding layer 240, surfaces of the first bonding layer 120 and the third bonding layer 240 are cleaned to remove organic and metallic contaminants. In an example process, a sulfuric acid hydrogen peroxide mixture (SPM), a mixture of ammonium hydroxide and hydrogen peroxide (SC1), or both may be used to remove organic contaminants on the first bonding layer 120 and the third bonding layer 240. A mixture of hydrochloric acid and hydrogen peroxide (SC2) may be used to remove metallic contaminants. Besides cleaning, the bonding contacts 124 and the bonding pads 248 may be treated by an argon plasma or a nitrogen plasma to activate the surfaces thereof. After the bonding contacts 124 and the bonding pads 248 are aligned, an anneal is performed to promote the van der Waals force bonding of the sixth dielectric bonding layer 122 and the fifth dielectric bonding layer 244 as well as the surface-activated bonding (SAB) of the bonding pads 248 and the bonding contacts 124. In the depicted example, the second plurality of bonding layers at block 508 include the first bonding layer 120 and the third bonding layer 240.

Referring to FIGS. 5 and 12, method 500 includes a block 510 where a substrate of the pixel chip is thinned. In FIG. 12, the third chip 30 corresponds to the pixel chip and the third substrate 302 corresponds to the substrate of the pixel chip. After the first chip 10 is bonded to the second chip 20, the chip stack shown in FIG. 11 is flipped upside down such that the back side 30B of the third chip 30 faces up, as shown in FIG. 12. After the flipping over, the third substrate 302 of the third chip 30 may undergo multiple thinning and polishing steps to reduce the thickness of the third substrate 302. In an example process, diamond wheels may be used to perform coarse grinding, fine grinding, or super fine grinding and a chemical mechanical polishing (CMP) process may be performed to polishing the ground third substrate 302.

Referring to FIGS. 4 and 5, method 500 includes a block 512 where further processes are performed to form an image sensor element. The image sensor element 40 in FIG. 4 corresponds to the image sensor element referred to at block 512. Such further processes may include formation of deep trench isolation (DTI) features 330, formation of a metal grid 332, deposition of passivation layers 334, formation of a color filter layer 336, formation of microlens 338, and formation of metal pads 340. To form the DTI features 330, deep trenches are formed into the third substrate 302 from the back side 30B (see FIG. 12). A liner and a fill material may then be deposited into the deep trenches to form DTI features 330. Because the DTI features 330 are formed over the back side 30B, the DTI features 330 may also be referred to as backside DTI (BDTI) features 330. In some embodiments, the liner may include a metal, such as aluminum (Al), tungsten (W), ruthenium (Ru), cobalt (Co), or copper (Cu) and the fill material may include a dielectric material, such as silicon oxide, aluminum oxide, hafnium oxide, titanium oxide, barium titanate, zirconium oxide, lanthanum oxide, barium oxide, strontium oxide, yttrium oxide, or a combination thereof.

The passivation layers 334 may include, for example, a first passivation layer and a second passivation layer. The composition of the passivation layers 334 may be the same as the composition of the fill material of the DTI features 330. The metal grid 332 may be embedded in the first passivation layer and the second passivation layer. The metal grid 332 is a grid-like structure or framework that extends over several, if not all, of the photodiodes 304. In some embodiments, the metal grid 332 may include tin (Sn), aluminum-copper (AlCu), aluminum (Al), tungsten (W), ruthenium (Ru), cobalt (Co), or copper (Cu). In an example process to form the metal grid 332, a metal layer is deposited over the first passivation layer. Then photolithography process and etch processes are used to pattern the metal layer into the metal grid 332. The second passivation layer is then deposited over the metal grid 332.

The color filter layer 336 may be formed of a polymeric material or a resin that includes color pigments. At block 512, the color filter layer 336 is formed over the second passivation layer of the passivation layers 334. The color filter layer 336 includes a plurality of filters each allowing for the transmission of radiation (e.g., light) having a specific range of wavelength, while blocking light of wavelengths outside of the specified range. Referring still to FIG. 4, microlens 338 are formed over the color filter layer 336. The microlens 338 may be formed of any material that may be patterned and formed into microlenses, such as a high transmittance acrylic polymer. In an embodiment, a microlens layer may be formed using a material in a liquid state and spin-on techniques. This method has been found to produce a substantially planar surface and a microlens layer having a substantially uniform thickness, thereby providing greater uniformity in the microlens 338. Other methods, such as CVD, PVD, or the like, may also be used. The planar material for the microlens layer may be patterned using a photolithography and etch technique to pattern the planar material in an array of microlens 338 corresponding to the photodiodes 304. The planar material may then be reflowed to form an appropriate curved surface for the microlens 338. The microlens 338 may be cured using an ultraviolet (UV) treatment.

To allow electrical connection through the thickness of the third substrate 302, the second substrate 202 is sawed along scribe lines to form openings that expose contact features in the third interconnect structure 310. Thereafter, a metal layer is deposited over the openings to form the metal pads 340. In some embodiments, the metal layer for the metal pads 340 may include copper (Cu), aluminum (Al), an aluminum-copper (AlCu) alloy, or titanium nitride.

Reference is still made to FIG. 4. The bonding pads 248 in the third bonding layer 240 are disposed at a first pitch Pl along the X direction. The bonding pads 328 in the fourth bonding layer 320 are disposed at a second pitch P2 along the X direction. By moving pixel transistors (such as source followers (SF) 206, reset transistors (RST) 208, and row selectors (SEL) 204) to the second chip, more space in the third chip 30 may be made available for photodiodes 304 and the pixel size may be reduced. As a result, the second pitch P2 is smaller than the first pitch P1. In some embodiments, a ratio of the second pitch P2 to the first pitch P1 may be between about 0.2 and about 0.75. In some instances, the first pitch P1 may be between about 1.5 μm and about 2.5 μm and the second pitch P2 may be between about 0.3 μm and about 1.5 μm.

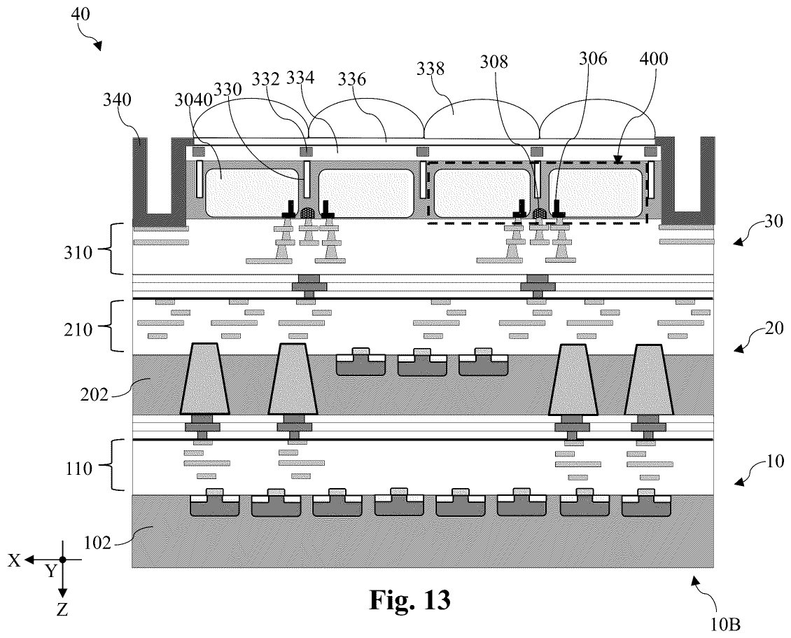

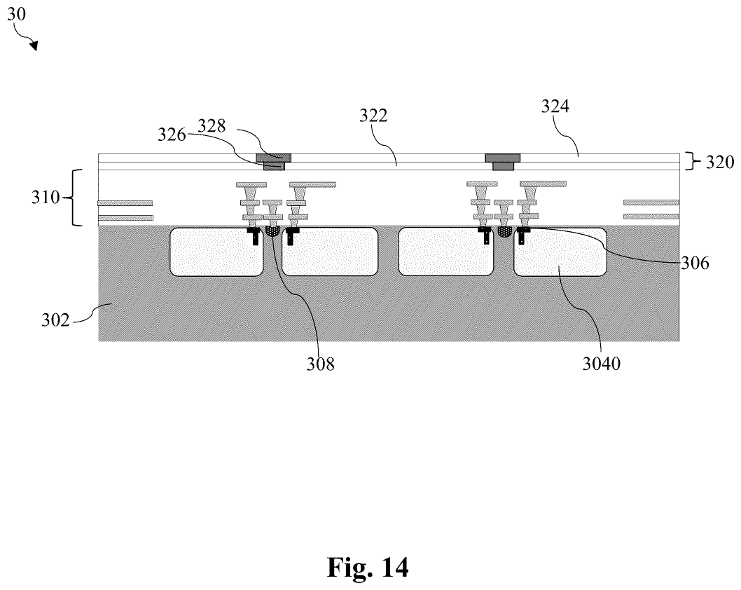

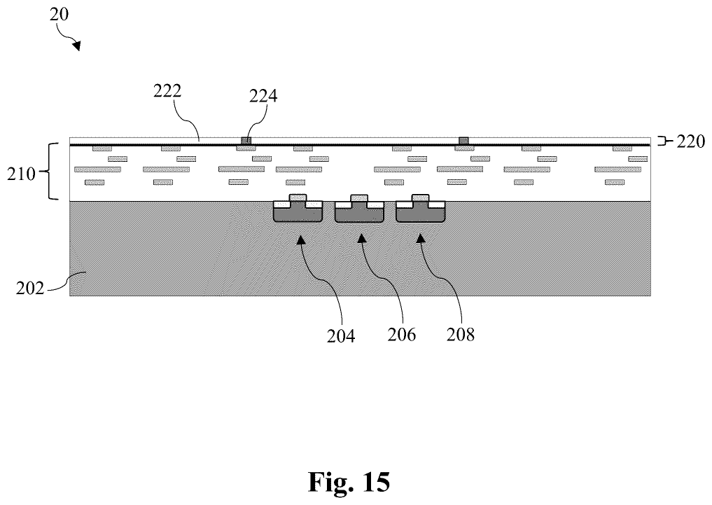

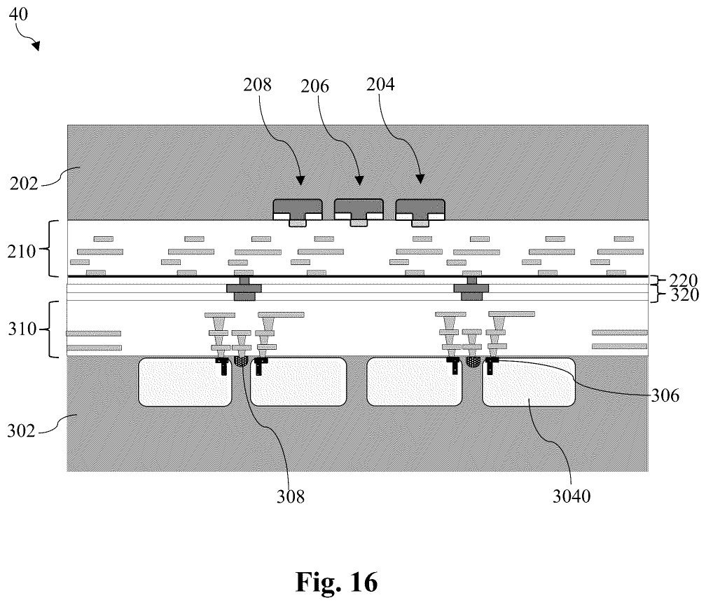

FIGS. 13-25 illustrate fabrication of the image sensor element 40 in FIG. 13 using method 500 in FIG. 5. Referring to FIGS. 5 and 14-16, method 500 includes a block 502 where a pixel device chip is bonded to a pixel chip by way of a first plurality of bonding layer. FIG. 14 illustrates a third chip 30 to correspond to a pixel chip and a second chip 20 to correspond to the pixel device chip. Because similar second chip 20 and third chip 30 have been described above, detailed description of them are omitted. Description is directed to the differences in these two embodiments shown in FIGS. 4 and 13. Instead of having photodiodes 304 shown in FIG. 6, the third substrate 302 includes large photodiodes 3040. As a result, the floating diffusion (FD) nodes 36 in the third chip 30 in FIG. 14 are more spaced apart. Reference is then made to FIG. 15. Due to the implementation of the large photodiodes 3040, the second chip 202 may include less row selector transistor 204, source follower transistor 206, and reset transistors 208. Because the bonding pads 328 and the bonding contacts 326 in the fourth bonding layer 320 are vertically aligned with the FD nodes 36, they are more spread out to have a larger pad pitch. Because the bonding contacts 224 in the second bonding layer 220 are configured to align with the bonding pads 328, the bonding contacts 224 too may be more dispersed and disposed at a greater pitch. As shown in FIG. 16, the second chip 20 is bonded to the third chip 30 by way of the second bonding layer 220 and the fourth bonding layer 320.

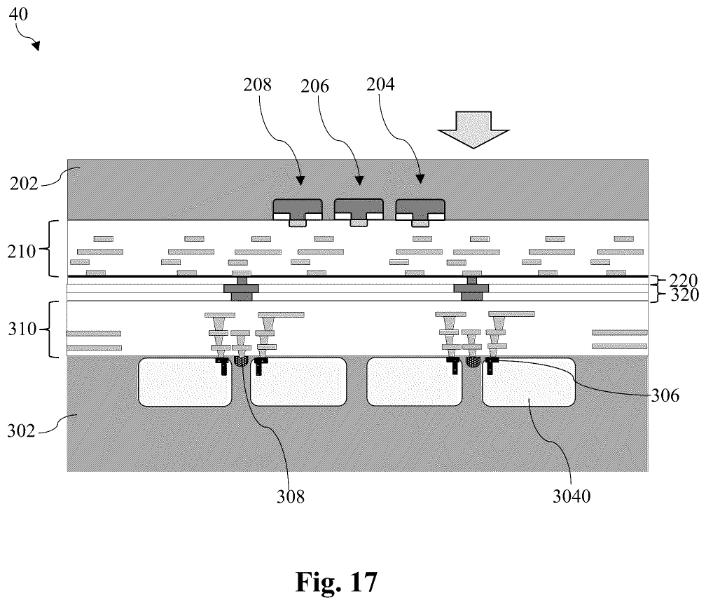

Referring to FIGS. 5 and 17, method 500 includes a block 504 where a substrate of the pixel device chip is thinned. The chip stack shown in FIG. 17 includes the second chip 20, which corresponds to a pixel device chip. At block 504, the second substrate 202 of the second chip is thinned. As a similar operation has been described above with reference to FIG. 9, detailed description of FIG. 17 is omitted.

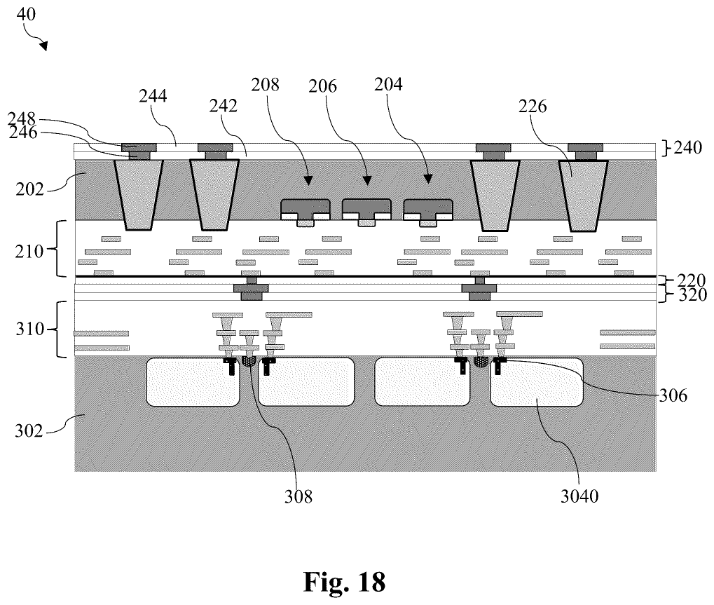

Referring to FIGS. 5 and 18, method 500 includes a block 506 where through-substrate-vias are formed through the substrate of the pixel device chip. As shown in FIG. 18, the second chip 20 corresponds to the pixel device chip and at block 506, through-substrate-vias (TSVs) 226 are formed through the second substrate 202 of the second chip 20. After the formation of the TSVs 226, a third bonding layer 240 is formed over the thinned second substrate 202. As shown in FIG. 18, each of the plurality of bonding pads 248 is vertically aligned or overlaps with one of the plurality of bonding contacts 246 along the Z direction. Furthermore, each of the plurality of bonding contacts 246 is vertically aligned with one of the TSVs 226. As a similar operation has been described above with reference to FIG. 10, detailed description of FIG. 18 is omitted.

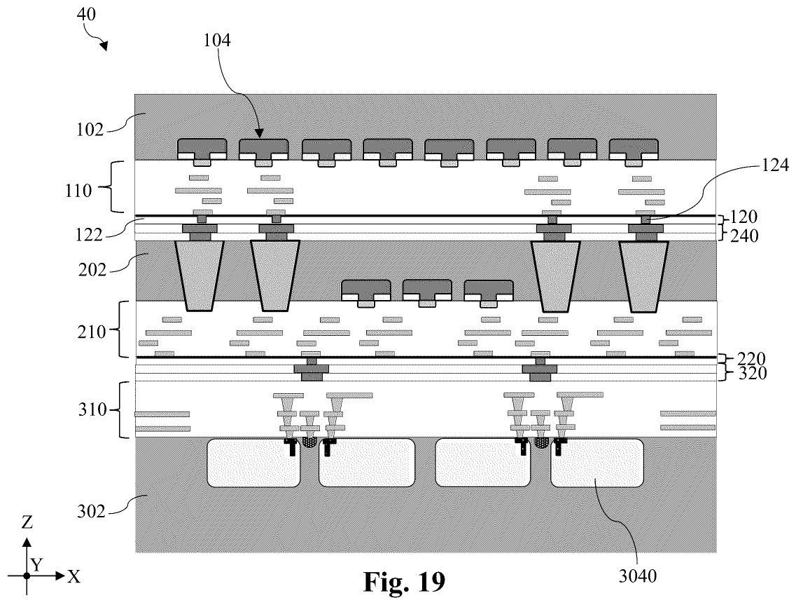

Referring to FIGS. 5 and 19, method 500 includes a block 508 where a logic chip is bonded to the pixel device chip by way of a second plurality of bonding layers. The first chip 10 corresponds to the logic chip and may be referred to as a logic chip 10. The first chip 10 includes a first bonding layer 120 deposited on the front side 10F of the first chip 10. In some embodiments represented in FIG. 19, the first bonding layer 120 includes a plurality of bonding contacts 124 disposed in a sixth dielectric bonding layer 122. It is noted that the first bonding layer 120 shown in FIG. 19 only includes bonding contacts 124 but does not include bonding pads similar to the bonding pads 328. In some alternative embodiments not explicitly shown in FIG. 19, the first bonding layer 120 may further include a plurality of bonding pads that are vertically aligned with the bonding contacts. At block 508, the first chip 10 is bonded to the second chip 20 by way of the third bonding layer 240 and the first bonding layer 120. As a similar operation has been described above with reference to FIG. 11, detailed description of FIG. 19 is omitted.

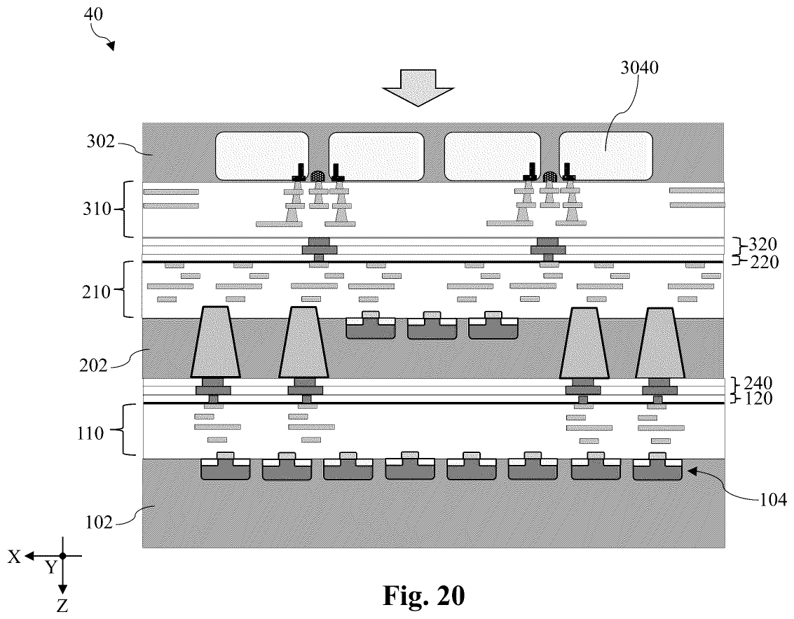

Referring to FIGS. 5 and 20, method 500 includes a block 510 where a substrate of the pixel chip is thinned. In FIG. 20, the third chip 30 corresponds to the pixel chip and the third substrate 302 corresponds to the substrate of the pixel chip. As a similar operation has been described above with reference to FIG. 12, detailed description of FIG. 20 is omitted.

Referring to FIGS. 5 and 13, method 500 includes a block 512 where further processes are performed to form an image sensor element. The image sensor element 40 in FIG. 13 corresponds to the image sensor element referred to at block 512. Such further processes may include formation of deep trench isolation (DTI) features 330, formation of a metal grid 332, deposition of passivation layers 334, formation of a color filter layer 336, formation of microlens 338, and formation of metal pads 340. As a similar operation has been described above with reference to FIG. 4, detailed description of FIG. 13 is omitted.

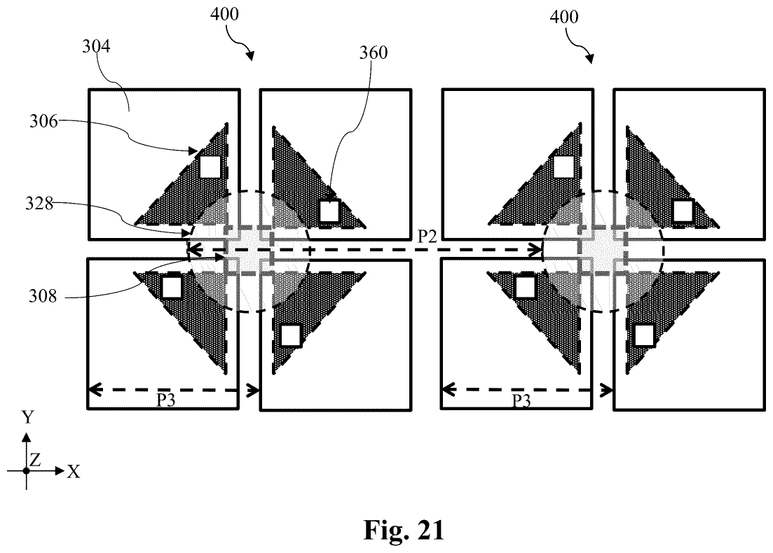

To help maximize the space for photodiodes 304 in FIG. 4 or large photodiodes 3040 in FIG. 13, photodiodes 304 (or large photodiodes 3040) may be grouped into clusters or units. FIG. 21 illustrates a schematic top view of two adjacent clusters 400. In some embodiments, each of the cluster 400 includes four photodiodes 304 or four large photodiodes 3040. In these embodiments, the two adjacent photodiodes 304 in FIG. 4 or two adjacent large photodiodes 3040 in FIG. 13 are actually two of the four photodiodes 304 (or large photodiodes 3040) in a cluster 400. For ease of reference, FIG. 21 includes 4 photodiodes 304. It should be understood that a similar configuration may apply to large photodiodes 3040 as well. As shown in FIG. 21, the four photodiodes 304 are arranged in a square formation to center around a FD node 308. Along the Z direction, each of the FD nodes 308 is aligned with a bonding pad 328 in the fourth bonding layer 320. A transfer gate transistor 306 is disposed at a corner of a photodiode 304 and is placed adjacent the shared FD node 308. This way, the four transfer gate transistors 306 may collect photo electrons generated in the four photodiodes 304 and direct the same to the FD node 308. Each of the transfer gate transistors 306 is coupled to a contact 360. As shown in FIG. 21, the photodiodes 304 are disposed at a third pitch P3 and the FD nodes 308 are disposed at the second pitch P2. In the embodiments represented in FIG. 21, the second pitch P2 is greater than the third pitch P3. In one embodiments, the second pitch P2 is about two times of the third pitch P3. It is noted that because the FD nodes 308 are vertically aligned with the bond pads 328, both the FD nodes 308 and the bond pads 328 are disposed at the second pitch P2 along the X direction.

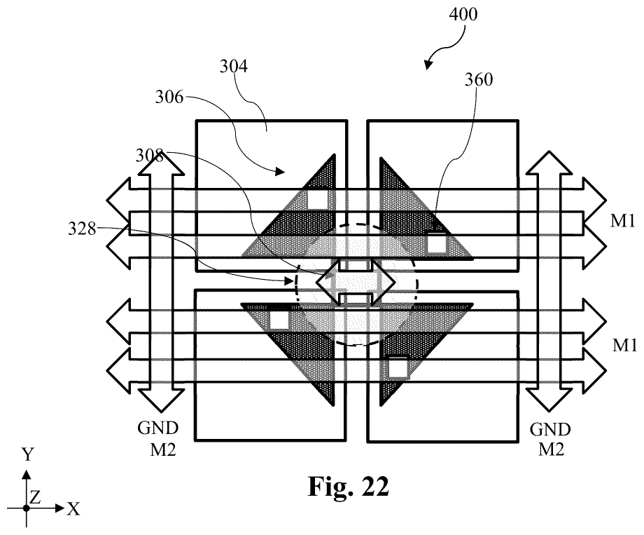

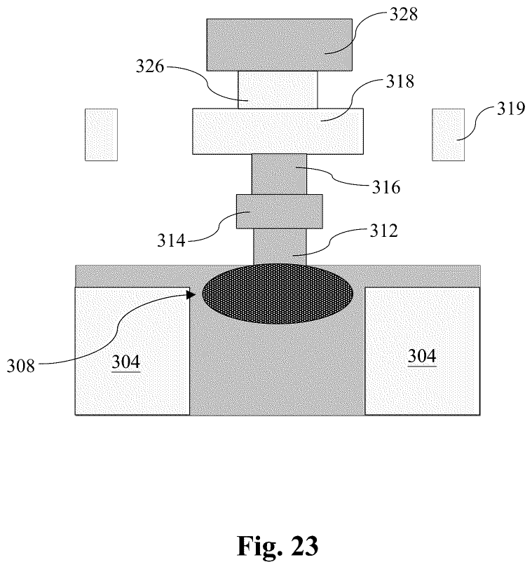

FIG. 22 illustrates a schematic top view of electrical routing around an image sensor cluster 400. In some embodiments, each of the contacts 360 is electrically connected to a metal line in a first metal layer (M1). In FIG. 22, the metal lines in the first metal layer (M1) extends lengthwise along the X direction. Two metal lines in the second metal layer (M2) extend along the Y direction to sandwich the cluster 400. In some instances, the two metal lines are connected to the ground (G or GND). Because current only flows from the FD nodes 36 to the second chip 20 along the Z direction, the FD node 36 is electrically coupled to a metal island 314 (shown in FIG. 23) in the first metal layer (M1). Unlike the metal lines in the first metal layer (M1), the metal island 314 does not extend beyond the boundaries of the cluster 400. FIG. 23 illustrates a schematic cross-sectional view of electrical routing around an image sensor cluster 400. The FD node 36 is physically and electrically coupled to a contact feature 312 that electrically couples the FD node 36 to the metal island 314. The metal island 314 is coupled to a top metal feature 318 in the second metal layer (M2) by way of a contact via 316. Two ground lines 319 are also disposed in the second metal layer (M2). A bonding contact 326 is disposed on the top metal feature 318 and a bonding pad 328 is vertically aligned and in contact with the bonding contact 326.

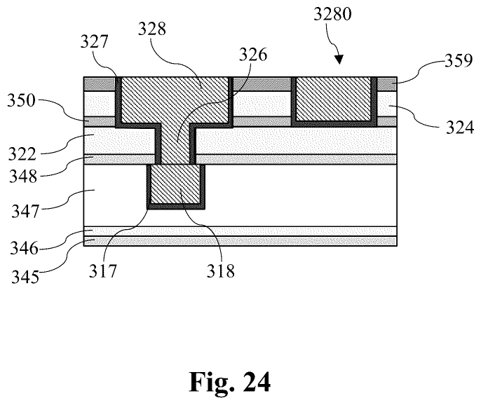

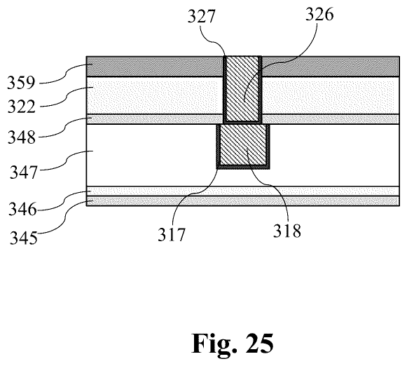

As described above, the bonding among the first chip 10, the second chip 20 and the third chip 30 is achieved by way of bonding layers. Two type of bonding layers, which are the first type and the second type, may be implemented according to embodiments of the present disclosure. The first type bonding layer includes a plurality of bonding contacts in a first dielectric bonding layer and a plurality of bonding pads in a second dielectric bonding layer. The plurality of bonding contacts are aligned with the plurality of bonding pads. The second type bonding layer includes a plurality of bonding contacts disposed in a dielectric bonding layer. An example of the first type bonding layer is the fourth bonding layer 320 shown in FIG. 6 and an example of the second type bonding layer is the second bonding layer 220 shown in FIG. 7. In general, the bonding pads in the second type bonding layer function to provide an even distribution of metal features, which is essential in achieving satisfactory chip bonding integrity and lifetime. It can be seen that the second type bonding layer is implemented when the top metal features or the bonding contacts are not evenly distribution on a surface of a chip. The first type bonding layer involves less processing steps and a lower cost. Further details of the first type bonding layer and the second type bonding layer are provided in conjunction with FIGS. 24 and 25.

FIG. 24 illustrates a schematic cross-sectional view of a first type bonding layer, according to various aspects of the present disclosure. With respect to each of the top metal features 318, the first type bonding layer includes a bonding contact 326 and a bonding pad 328 which are vertically aligned with one another. The first type bonding layer may include dummy bonding pads 3280 that are not electrically coupled to any bonding contacts below. Those dummy bonding pads 3280 are inserted to provide an even metal feature density. In some embodiments, the top metal feature 318 is embedded in an IMD layer 347 which is disposed over a first etch stop layer (ESL) 345 and a second etch stop layer (ESL) 346. The IMD layer 347 may include tetraethylorthosilicate (TEOS) oxide, un-doped silicate glass, or doped silicon oxide such as borophosphosilicate glass (BPSG), fused silica glass (FSG), phosphosilicate glass (PSG), or boron doped silicon glass (BSG). The first ESL 345 may include silicon carbide. The second ESL 346 may include silicon oxide. A third ESL 348 is disposed over the IMD layer 347 and a first dielectric bonding layer 322 is disposed over the third ESL 348. The bonding contact 326 extends through the third ESL 348 and the first dielectric bonding layer 322. The first dielectric bonding layer 322 may share the same composition with the second ESL 346, which may include silicon oxide. The third ESL 348 includes silicon carbide. A fourth ESL 350 is disposed over the first dielectric bonding layer 322 and a second dielectric bonding layer 324 is disposed over the fourth ESL 350. The fourth ESL 350 may include silicon nitride and the second dielectric bonding layer 324 may include silicon oxide. In some embodiments, a block layer 359 may be disposed over the second dielectric bonding layer 324. The block layer 359 may include silicon oxynitride and functions to prevent electromigration when metal bonding contacts or bonding pads from the other chip are not fully aligned with the bonding pads 328. The bonding pad 328 extends through the block layer 359, the second dielectric bonding layer 324 and the fourth ESL 350. In some embodiments represented in FIG. 24, the bonding pad 328 and the bonding contact 326 are formed using a dual damascene process and are continuous. To prevent electromigration and oxygen diffusion, the top metal feature 318 is isolated from the IMD layer 347 by a first barrier layer 317 and the bonding contact 326 and the bonding pad 328 are isolated from the surrounding dielectric layers by a second barrier layer 327. The first barrier layer 317 and the second barrier layer 327 may include titanium nitride or tantalum nitride. The dummy bonding pad 3280 shares a similar construction with the bonding pad 328.

FIG. 25 illustrates a schematic cross-sectional view of a second type bonding layer, according to various aspects of the present disclosure. As shown in FIG. 25, the second type bonding layer includes only the bonding contact 326 embedded in the first dielectric bonding layer 322. To prevent electromigration when metal bonding contacts or bonding pads from the other chip (to be bonded) are not fully aligned with the bonding contacts 326, the block layer 359 is disposed over the first dielectric bonding layer 322.

Thus, in some embodiments, the present disclosure provides a device structure that includes a first die having a first substrate and a first interconnect structure disposed over the first substrate, a second die having a second substrate and a second interconnect structure disposed over the second substrate, and a third die having a third interconnect structure and a third substrate disposed over the third interconnect structure. The first interconnect structure is bonded to the second substrate by way of a first plurality of bonding layers. The second interconnect structure is bonded to the third interconnect structure by way of a second plurality of bonding layers. The third substrate includes a plurality of photodiodes and a first transistor disposed over the third substrate. The second die includes a second transistor having a source electrically connected to a drain of the first transistor, a third transistor having a gate electrically connected to drain of the first transistor and the source of the second transistor, and a fourth transistor having a drain electrically connected to the source of the third transistor.

In some embodiments, the first plurality of bonding layers include a first plurality of bonding pad structures disposed at a first pitch and the second plurality of bonding layers includes a second plurality of bonding pad structures disposed at a second pitch different from the first pitch. In some implementations, the second pitch is smaller than the first pitch. In some embodiments, the first pitch is between about 1.5 μm and about 2.5 μm and the second pitch is between about 0.3 μm and about 1.5 μm. In some embodiments, a ratio of the second pitch to the first pitch is between about 0.2 and about 0.75. In some implements, the third die includes a plurality of floating diffusion regions. Each of the plurality of floating diffusion regions is vertically aligned with one of the second plurality of bonding pad structures. In some instances, a gate structure of the first transistor is in physical contact with one of the plurality of photodiodes. In some embodiments, the second die includes a plurality of through-substrate-vias (TSVs) extending through the second substrate.

Another aspect of the present disclosure involves a device structure that includes a first plurality of bonding layers including a first plurality of bonding pad structures and a first die. The first die includes a first interconnect structure disposed over the first plurality of bonding layers, a first substrate disposed over the first interconnect structure, a plurality of photodiodes disposed in the first substrate, and a plurality of floating diffusion regions disposed among the plurality of photodiodes. Each of the plurality of floating diffusion regions is vertically aligned with one of the first plurality of bonding pad structures.

In some embodiments, the device structure further includes a second die that includes a second substrate, and a second interconnect structure disposed over the second substrate. The second interconnect structure is bonded to the first interconnect structure by way of the first plurality of bonding layers. In some implementations, the die structure further includes a third die that includes a third substrate and a third interconnect structure disposed over the third substrate. The third interconnect structure is bonded to the second substrate by way of a second plurality of bonding layers. In some instances, the second plurality of bonding layers includes a second plurality of bonding pad structures and wherein the second substrate includes a plurality of through-substrate-vias (TSVs). In some embodiments, each of the second plurality of bonding pad structures is vertically aligned with one of the plurality of TSVs. In some embodiments, the first plurality of bonding pad structures is disposed at a first pitch and the second plurality of bonding pad structures is disposed at a second pitch different from the first pitch. In some implementations, wherein the first pitch is between about 0.3 μm and about 1.5 μm and wherein the second pitch is between about 1.5 μm and about 2.5 μm.

Yet another aspect of the present disclosure involves a method that includes a first plurality of bonding layers including a first plurality of bonding pad structures and a first die. The first die includes a first interconnect structure disposed over the first plurality of bonding layers, a first substrate disposed over the first interconnect structure, a plurality of photodiodes disposed in the first substrate, and a plurality of floating diffusion regions disposed among the plurality of photodiodes. Each of the plurality of floating diffusion regions is vertically aligned with one of the first plurality of bonding pad structures.

In some embodiments, the device structure further includes a second die that includes a second substrate and a second interconnect structure disposed over the second substrate. The second interconnect structure is bonded to the first interconnect structure by way of the first plurality of bonding layers. In some implementations, the device structure further includes a third die that includes a third substrate and a third interconnect structure disposed over the third substrate. The third interconnect structure is bonded to the second substrate by way of a second plurality of bonding layers. In some embodiments, the second plurality of bonding layers include a second plurality of bonding pad structures and the second substrate includes a plurality of through-substrate-vias (TSVs). In some implementations, each of the second plurality of bonding pad structures is vertically aligned with one of the plurality of TSVs. In some instances, the first plurality of bonding pad structures is disposed at a first pitch. The second plurality of bonding pad structures is disposed at a second pitch different from the first pitch. In some instances, the first pitch is between about 0.3 μm and about 1.5 μm and the second pitch is between about 1.5 μm and about 2.5 μm.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit line conductor and word line conductor, one can achieve different resistances for the conductors. However, other techniques to vary the resistances of the metal conductors may also be utilized as well.

What is claimed is:

1. A device structure, comprising:
a first substrate comprising a plurality of logic transistors;
a first interconnect structure over the first substrate;
a first bonding layer over the first interconnect structure, the first bonding layer comprising first bonding contacts;
a second bonding layer over the first bonding layer, the second bonding layer comprising second bonding contacts;
a second substrate over the second bonding layer and comprising row selector transistors, source follower transistors, and reset transistors;
a second interconnect structure over the second substrate;
a third bonding layer over the second interconnect structure, the third bonding layer comprising third bonding contacts;
a fourth bonding layer over the third bonding layer, the fourth bonding layer comprising fourth bonding contacts;
a third interconnect structure over the fourth bonding layer; and
a third substrate over the third interconnect structure and comprising a first number of floating diffusion regions and a second number of photodiodes,
wherein the first bonding contacts are vertically aligned and bonded to the second bonding contacts,
wherein the third bonding contacts are vertically aligned with and bonded to the fourth bonding contacts,
wherein along a direction, the first bonding contacts are disposed at a first pitch,
wherein along the direction, the third bonding contacts are disposed at a second pitch smaller than the first pitch, and
wherein the first number is smaller than the second number.

2. The device structure of claim 1, wherein a ratio of the second number to the first number is 4.

3. The device structure of claim 1, further comprising a plurality of through substrate vias extending through the second substrate.

4. The device structure of claim 1, wherein each of the plurality of through substrate vias is aligned with and interfaces one of the second bonding contacts.

5. The device structure of claim 4, wherein the plurality of through substrate vias tapers upward such a width of the plurality of through substrate vias adjacent the second bonding layer is greater than a width of the plurality of through substrate vias away from the second bonding layer.

6. The device structure of claim 3, wherein the first number of floating diffusion regions are vertically aligned with the fourth bonding contacts.

7. The device structure of claim 3,
wherein the third substrate further comprises the second number of transfer gate transistors,
wherein a gate of each of the second number of transfer gate transistors extends into one of the second number of photodiodes.

8. The device structure of claim 1, further comprising:
a metal grid over the third substrate;
a color filter layer over the metal grid; and
microlens over the color filter layer.

9. The device structure of claim 1, wherein each of the first number of floating diffusion regions is surrounded by 4 of the second number of photodiodes.

10. The device structure of claim 1, wherein the first substrate, the second substrate, and the third substrate comprise silicon.

11. A device structure, comprising:
a first substrate comprising a plurality of logic transistors;
a first interconnect structure over the first substrate;
a first bonding layer over the first interconnect structure, the first bonding layer comprising first bonding contacts;
a second bonding layer over the first bonding layer, the second bonding layer comprising second bonding contacts;
a second substrate over the second bonding layer and comprising row selector transistors, source follower transistors, and reset transistors;
a plurality of through substrate vias extending through the second substrate;
a second interconnect structure over the second substrate;
a third bonding layer over the second interconnect structure, the third bonding layer comprising third bonding contacts;
a fourth bonding layer over the third bonding layer, the fourth bonding layer comprising fourth bonding contacts;
a third interconnect structure over the fourth bonding layer; and
a third substrate over the third interconnect structure and comprising a first number of floating diffusion regions and a second number of photodiodes,
wherein the first bonding contacts are vertically aligned and bonded to the second bonding contacts,
wherein the third bonding contacts are vertically aligned with and bonded to the fourth bonding contacts,
wherein along a direction, the first bonding contacts are disposed at a first pitch,
wherein along the direction, the third bonding contacts are disposed at a second pitch different from the first pitch, and
wherein each of the plurality of through substrate vias is aligned with and interfaces one of the second bonding contacts.

12. The device structure of claim 11, wherein the second pitch is smaller than the first pitch.

13. The device structure of claim 11, wherein the first number is smaller than the second number.

14. The device structure of claim 11, wherein the plurality of through substrate vias tapers upward such a width of the plurality of through substrate vias adjacent the second bonding layer is greater than a width of the plurality of through substrate vias away from the second bonding layer.

15. The device structure of claim 11, wherein the first number of floating diffusion regions are vertically aligned with the fourth bonding contacts.

16. The device structure of claim 11,
wherein the third substrate further comprises the second number of transfer gate transistors,
wherein a gate of each of the second number of transfer gate transistors extends into one of the second number of photodiodes.

17. The device structure of claim 11, wherein a ratio of the second number to the first number is 4.

18. A device structure, comprising:
a first substrate comprising a plurality of logic transistors;
a first interconnect structure over the first substrate;
a first bonding layer over the first interconnect structure, the first bonding layer comprising first bonding contacts;
a second bonding layer over the first bonding layer, the second bonding layer comprising second bonding contacts;
a second substrate over the second bonding layer and comprising row selector transistors, source follower transistors, and reset transistors;
a plurality of through substrate vias extending through the second substrate;
a second interconnect structure over the second substrate;
a third bonding layer over the second interconnect structure, the third bonding layer comprising third bonding contacts;
a fourth bonding layer over the third bonding layer, the fourth bonding layer comprising fourth bonding contacts;
a third interconnect structure over the fourth bonding layer; and
a third substrate over the third interconnect structure and comprising a first number of floating diffusion regions, a second number of photodiodes, and a second number of transfer gate transistors,
wherein the first bonding contacts are vertically aligned and bonded to the second bonding contacts,
wherein the third bonding contacts are vertically aligned with and bonded to the fourth bonding contacts,
wherein along a direction, the first bonding contacts are disposed at a first pitch,
wherein along the direction, the third bonding contacts are disposed at a second pitch different from the first pitch,
wherein a gate of each of the second number of transfer gate transistors extends into one of the second number of photodiodes, and
wherein the first number is smaller than the second number.

19. The device structure of claim 18, wherein each of the plurality of through substrate vias is aligned with and interfaces one of the second bonding contacts.

20. The device structure of claim 18, wherein the plurality of through substrate vias tapers upward such a width of the plurality of through substrate vias adjacent the second bonding layer is greater than a width of the plurality of through substrate vias away from the second bonding layer.
